(19) United States
(12) Patent Application Publication
(10) Pub. No.: US 2026/0150635 A1
(43) Pub. Date: May 28, 2026

(54) INHIBITED ATOMIC LAYER DEPOSITION FOR PATTERNING APPLICATIONS

(71) Applicant: Lam Research Corporation, Fremont, CA (US)

(72) Inventors: Jennifer Leigh PETRAGLIA, Portland, OR (US); Ravi KUMAR, Beaverton, OR (US); Andrew Geier MELTON, Portland, OR (US); Dara BOBB SEMPLE, Sunnyvale, CA (US)

(21) Appl. No.: 19/122,562

(22) PCT Filed: Nov. 8, 2023
(86) PCT No.: PCT/US2023/079084

§ 371 Date: Apr. 18, 2025

Related U.S. Application Data
(60) Provisional application No. 63/383,883, filed on Nov. 15, 2022.

(51) Int. Cl. H10P 76/40; C23C 16/04; C23C 16/455; C23C 16/52; H10P 14/60

(52) U.S. Cl. CPC H10P 76/4085; C23C 16/042; C23C 16/45536; C23C 16/52; H10P 14/6339

(57) ABSTRACT

Examples are disclosed related to using an inhibitor in an atomic layer deposition (ALD) process to deposit a film in a patterning process. One example provides a method of processing a substrate comprising a gap between spacers. The method comprises performing a plurality of atomic layer deposition (ALD) cycles to fill the gap between the spacers with an oxide film. An ALD cycle of the plurality of ALD cycles comprises exposing the substrate to an inhibitor under conditions configured to deposit inhibitor at a first depth within the gap at a relatively greater concentration than at a second depth within the gap. The second depth is deeper in the gap than the first depth. The method further comprises, after filling the gap between the spacers, performing an etching cycle to expose the spacers. The method further comprises removing the spacers.

### BACKGROUND

Electronic device fabrication processes may involve many steps of material deposition, patterning, and removal to form integrated circuits on substrates. Various methods can be used to process films of materials to form integrated circuits. For example, atomic layer deposition (ALD) can be used to form a film on a substrate in a layer-by-layer manner using one or more deposition cycles. In an ALD cycle, a film precursor gas is adsorbed onto a surface of a substrate disposed in a processing chamber. Excess film precursor is purged from the processing chamber, and the adsorbed film precursor is chemically converted into a film on the substrate. For example, the adsorbed precursor can be oxidized to form an oxide film. A highly conformal film of a target thickness can be grown using one or more deposition cycles.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed related to using an inhibitor in an ALD process to avoid forming a seam when filling a gap on a substrate. One example provides a method of processing a substrate comprising a gap between spacers. The method comprises performing a plurality of atomic layer deposition (ALD) cycles to fill the gap between the spacers with an oxide film. An ALD cycle of the plurality of ALD cycles comprises exposing the substrate to an inhibitor under conditions configured to deposit inhibitor into the gap such that a concentration of the inhibitor deposited at a first depth within the gap is greater than a concentration of the inhibitor deposited at a second depth within the gap. The second depth is deeper in the gap than the first depth. The method further comprises, after filling the gap between the spacers, performing an etching cycle to expose the spacers. The method further comprises removing the spacers.

In some such examples, the inhibitor comprises a carbon-containing inhibitor.

In some such examples, the carbon-containing inhibitor additionally or alternatively comprises one or more of an alkane, an alkene, an alkyne, a cyclic hydrocarbon, an alcohol, a diol, an aldehyde, an ester, an ether, a ketone, an alkyl halide, an alkyl amine, or an alkyl diamine.

In some such examples, the inhibitor additionally or alternatively comprises a nitrogen-containing inhibitor.

In some such examples, the nitrogen-containing inhibitor additionally or alternatively comprises one or more of nitrogen, ammonia, an amine, a diamine, or an aminoalcohol.

In some such examples, exposing the substrate to an inhibitor additionally or alternatively comprises forming a plasma comprising the inhibitor.

In some such examples, the inhibitor additionally or alternatively comprises a fluorine-containing inhibitor.

In some such examples, the fluorine-containing inhibitor additionally or alternatively comprises one or more of fluorine, nitrogen trifluoride, or a fluorocarbon.

In some such examples, the method additionally or alternatively further comprises performing an ALD cycle of the plurality of ALD cycles that omits exposing the substrate to the inhibitor.

In some such examples, two of more ALD cycles of the plurality of ALD cycles comprise exposing the substrate to the inhibitor.

Another example provides an atomic layer deposition (ALD) tool. The ALD tool comprises a processing chamber. The ALD tool further comprises a substrate support disposed in the processing chamber. The ALD tool further comprises a film precursor source comprising a film precursor. The ALD tool further comprises an oxidant gas source comprising an oxidant. The ALD tool further comprises an inhibitor source comprising an inhibitor. The ALD tool further comprises flow control hardware configured to control flows of the film precursor, the oxidant, and the inhibitor into the processing chamber. The ALD tool further comprises a radiofrequency power source configured to form a plasma in the processing chamber. The ALD tool further comprises a controller configured to control the ALD tool to operate the flow control hardware to introduce the inhibitor into the processing chamber under conditions configured to deposit inhibitor within a gap between spacers on a substrate such that a concentration of the inhibitor deposited at a first depth within the gap is greater than a concentration of the inhibitor deposited at a second depth within the gap. The second depth is deeper in the gap than the first depth. The controller is further configured to operate the flow control hardware to introduce the film precursor to the processing chamber to adsorb the film precursor on the substrate. The controller is further configured to operate the flow control hardware and the radiofrequency power source to introduce the oxidant into the processing chamber and to form a plasma to oxidize the film precursor to form a layer of the oxide film.

In some such examples, the film precursor comprises one or more of a silicon-containing precursor, an aluminum-containing precursor, a hafnium-containing precursor, a titanium-containing precursor, a tungsten-containing precursor, a tin-containing precursor, or a molybdenum-containing precursor.

In some such examples, the inhibitor additionally or alternatively comprises a carbon-containing inhibitor.

In some such examples, the carbon-containing inhibitor additionally or alternatively comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

In some such examples, the inhibitor additionally or alternatively comprises a nitrogen-containing inhibitor.

In some such examples, the inhibitor additionally or alternatively comprises a fluorine-containing inhibitor.

In some such examples, the controller additionally or alternatively is further configured to operate the ALD tool to perform a passivation step to remove at least some of the inhibitor from the substrate.

Another example provides a structure formed on a substrate in an integrated circuit manufacturing process. The structure comprises a plurality of spacers located on a surface of the substrate, the plurality of spacers defining one or more gaps. The structure further comprises an oxide film at least partially filling the one or more gaps. The structure further comprises an inhibitor deposited within the one or more gaps, a concentration of the inhibitor deposited at a first depth within the one or more gaps being greater than a concentration of inhibitor deposited at a second depth within the one or more gaps, the second depth being deeper in the gap than the first depth, the inhibitor configured to inhibit growth of the oxide film.

In some such examples, the substrate additionally or alternatively comprises a feature-dense region comprising the two or more spacers, an expanse lacking features, and the inhibitor is further deposited on the expanse lacking features.

In some such examples, the oxide film additionally or alternatively comprises one of silicon oxide, tin oxide, titanium oxide, tungsten oxide, hafnium oxide, aluminum oxide, or molybdenum oxide.

### BRIEF DESCRIPTION OF THE DRAWINGS

FIGS. 1A-1F schematically illustrate structures formed in a patterning process including an ALD gapfill process that omits the use of an inhibitor.

FIG. 2 shows a block diagram of an example ALD tool.

FIGS. 3A-3B schematically show an example of chemisorption of an inhibitor on a substrate comprising gaps between spacers.

FIGS. 4A-4G schematically illustrate structures formed in an example patterning process including an example ALD gapfill process comprising an inhibitor.

FIGS. 5A-5D schematically illustrate structures formed in another example patterning process including an ALD gapfill process comprising an inhibitor.

FIGS. 6A-6E schematically illustrate structures formed in another example patterning process performed on a substrate comprising a feature-dense region and an expanse lacking features.

FIG. 7 shows a flow diagram of an example ALD cycle that omits an inhibitor.

FIG. 8 shows a flow diagram of an example ALD cycle that includes an inhibitor.

FIG. 9 shows a flow diagram of another example ALD cycle that includes an inhibitor.

FIG. 10 shows a flow diagram of an example method for performing ALD processing using a plurality of ALD cycles.

FIG. 11 shows a flow diagram of an example method for performing ALD processing using a plurality of ALD cycles and a passivation step.

FIG. 12 shows a flow diagram of another example method for performing ALD processing using a plurality of ALD cycles and a plurality of passivation steps.

FIG. 13 shows a flow diagram of another example method for performing ALD processing using a plurality of ALD cycles and a plurality of passivation steps.

FIG. 14 shows a block diagram of an example computing system.

### DETAILED DESCRIPTION

The term “alcohol” may generally represent hydrocarbon compounds comprising a general formula of R—OH, where R is an aromatic or aliphatic group. Alcohols may have one OH group and examples of such alcohols comprise methanol, ethanol, and propanol. Alcohols may have more than one OH group (polyols), such as diols, which have two OH functional groups. Example diols comprise ethane-1,2-diol, propane-1,2-diol and propane-1,3-diol. Example polyols comprise glycerol (propane-1,2,3-triol).

The term “aldehyde” may generally represent hydrocarbon compounds comprising a terminal carbonyl group. Aldehydes comprise a general formula of R—CHO where R is an aromatic or aliphatic group. Example aldehydes comprise formaldehyde and acetaldehyde.

The term “aliphatic” may generally represent organic compounds lacking aromatic groups.

The term “alkane” may generally represent compounds comprising a general formula CₙH₂ₙ₊₂ and substituted variants thereof. Example alkanes include methane, ethane, propane, and butane. Example alkanes that may be suitable for use as a carbon-containing inhibitor may comprise a general formula CₙH₂ₙ₊₂ in which n=1 to 10.

The term “alkene” may generally represent hydrocarbon compounds comprising at least one carbon-carbon double bond. Alkanes comprising one carbon-carbon double bond may be represented by a general formula of CₙH₂ₙ and substituted variants thereof. Example alkenes include ethylene, propylene, and butylenes. Alkenes may have more than one carbon-carbon double bond, such as dienes, allenes, and cumulenes. Example alkenes that may be suitable for use as a carbon-containing inhibitor may comprise a general formula CₙH₂ₙ in which n=2 to 10.

The term “alkyl amine” may generally represent hydrocarbon compounds comprising a nitrogen with 1 to 3 alkyl substituents and 0 to 2H substituents. Alkyl amines comprise primary, secondary, tertiary, and cyclic amines. Examples of alkyl amines include methylamine, dimethylamine, trimethylamine, and piperidine.

The term “alkyl halide” may generally represent hydrocarbon compounds comprising a halogen. Examples of alkyl halides comprise ethyl fluoride (fluoroethane), isopropyl bromide (2-bromopropane), and t-butyl chloride (2-chloro-2-methylpropane). Alkyl halides may comprise two or more halogen groups, such as 1,2-dichlorobutane.

The term “alkyne” may generally represent hydrocarbon compounds comprising at least one carbon-carbon triple bond. Alkynes comprising one carbon-carbon triple may be represented by a general formula of CₙH₂ₙ₋₂ and substituted variants thereof. Alkynes may have more than one carbon-carbon triple bond, such as diynes, which have two carbon-carbon triple bonds. Example alkynes that may be suitable for use as a carbon-containing inhibitor may comprise a general formula CₙH₂ₙ₋₂ in which n=2 to 10.

The term “aromatic” may generally represent a planar cyclic compound comprising pi bonding in resonance. The term “aromatic” comprises homocyclic compounds in which all atoms in a ring structure are carbon, and also heterocyclics in which one or more atoms in a ring structure are elements other than carbon (e.g. nitrogen).

The term “aspect ratio” may generally represent a ratio between a depth of a feature such as a substrate gap and an average width of the feature.

The term “atomic layer deposition” (ALD) may generally represent a process in which a film is formed on a substrate in one or more individual layers by sequentially adsorbing a precursor conformally to the substrate and reacting the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The terms “growth” and “deposition”, and variants thereof, also may be used to refer to film formation.

The term “ALD cycle” may generally represent a sequence of processes used to form a layer of a film in an ALD process.

The term “ALD cycle comprising an inhibitor” may generally represent an ALD cycle that includes introduction of an inhibitor to a processing chamber during the cycle.

The term “ALD tool” may generally represent a machine comprising a processing chamber and other hardware configured to perform ALD processing.

The term “cyclic hydrocarbon” may generally represent saturated and unsaturated hydrocarbon molecules comprising a closed ring structure, and substituted variants thereof. Example cyclic hydrocarbons include cyclopropane and cyclobutene. Example cyclic hydrocarbons also include aromatics such as benzene, toluene, and xylene.

The term “ether” may generally represent hydrocarbon compounds comprising the general formula R—O—R′ where R and R′ are independently an aromatic or aliphatic group. Example ethers comprise diethyl ether, methyl phenyl ether, and cyclic ethers such as furan.

The term “ester” may generally represent hydrocarbon compounds comprising the general formula R—C(O) OR′ where R and R′ are independently any aromatic or aliphatic group and wherein R may alternatively comprise H (e.g., formate). Examples esters comprise ethyl formate, methyl acetate, and ethyl acetate.

The term “expanse lacking features” may generally represent a substrate region without positive topological features such as mandrels, or negative topological features such as gaps.

The term “film precursor” may generally represent any material that can be introduced into a processing chamber to form an oxide film on a substrate disposed within the processing chamber. Examples of film precursors include silicon-containing precursors that can be used to form silicon-containing films such as silicon dioxide, silicon oxynitride, and silicon oxycarbide films. Other examples of film precursors include metal-containing precursors for forming metal oxide films. Examples of such metal-containing precursors include aluminum-containing precursors, hafnium-containing precursors, titanium-containing precursors, tungsten-containing precursors, tin-containing precursors, and molybdenum-containing precursors, which respectively may be used to form aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

The term “silicon-containing precursor” may generally represent any material that can be introduced into a processing chamber in a gas phase to form a silicon-containing oxide film on the substrate. Example film precursors for forming silicon-containing films using PEALD may comprise materials having the general structure:

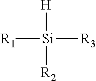

where R₁, R₂ and R₃ may be the same or different substituents, and may include silanes, siloxy groups, amines, halides, hydrogen, or organic groups, such as alkylamines, alkoxy, alkyl, alkenyl, alkynyl, and aromatic groups.

Example silicon-containing precursors include silane, polysilanes (H₃Si—(SiH₂)ₙ—SiH₃), where n≥0, such as disilane, trisilane, and tetrasilane, and trisilylamine.

In some examples, the silicon-containing precursor is an alkoxysilane. Alkoxysilanes that may be used include the following:
Hₓ—Si—(OR)_{y}, where x=1−3, x+y=4 and each R is a substituted or unsubstituted alkyl, substituted or unsubstituted alkenyl, substituted or unsubstituted alkynyl, or substituted or unsubstituted aromatic group; and Hₓ(RO)_{y}, —Si—Si—(OR)_{y}Hₓ, is a substituted or unsubstituted alkyl, substituted or unsubstituted alkenyl, substituted or unsubstituted alkynyl, or substituted or unsubstituted aromatic group.

Examples of silicon-containing precursors include tetraethyl orthosilicate (TEOS), tetramethoxysilane (TMOS), methylsilane, trimethylsilane (3 MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor may be an aminosilane, such as bisdiethylaminosilane, diisopropylaminosilane, bis(t-butylamino) silane (BTBAS), di-sec-butylaminosilane, or tris(dimethylamino) silane (3DMAS). Aminosilane precursors may have the general formula: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

In some examples, a halogen-containing silane may be used such that the silane includes at least one hydrogen atom. Such a silane may have a chemical formula of SiXₐH_{y} where X is a halogen and y≥1. Dichlorosilane (H₂SiCl₂) may be used in some examples.

An example precursor for providing nitrogen for formation of a silicon oxynitride film is N₂O.

Example aluminum-containing precursors for forming aluminum oxide films (Al₂O₃) include aluminum halides (AlX₃), trimethylaluminum (Al(CH₃)₃), aluminum alkoxides such as aluminum ethoxide (Al(OC₂H₅)₃), and aluminum amides such as tris(dimethylamido) aluminum (Al(N(CH₃)₂)₃).

Example hafnium-containing precursors for forming hafnium oxide films (HfOₓ) include hafnium tetrachloride (HfCl₄), tetrakis(diethylamino) hafnium (Hf(N(C₂H₅)₂)₄), and tetrakis(tert-butoxide) hafnium (Hf(OC(CH₃)₃)₄).

Examples of titanium-containing precursors for forming titanium oxide films (TiOₓ) include titanium tetrachloride (TiCl₄) and titanium isopropoxide (Ti(OCH(CH₃)₂)₄).

Examples of tungsten-containing precursors for forming tungsten oxide films (WOₓ) include tungsten hexafluoride (WF₆), tungsten hexachloride (WCl₆), bis(tert-butylimino)bis(dimethylamino) tungsten (C₁₂H₃₀N₄W), and tungsten hexacarbonyl (W(CO)₆).

Examples of tin-containing precursors for forming tin oxide films (SnOₓ) include tin tetrachloride (SnCl₄), tetramethyltin ((CH₃)₄Sn), tetraethyltin ((C₂H₅)₄Sn), dimethyltin dichloride ((CH₃)₂SnCl₂), dibutyl (dimethoxy) stannane (Bu₂Sn(OMe)₂), tetrakis(dimethylamido) tin (IV) (Sn(NMe₂)₄), dimethylamino dimethyl tin (Me₂Sn(NMe₂)₂), and dimethylamino trimethyl tin (Me₃Sn(NMe₂)), where Bu represents a butyl group (C₄H₉) and Me represents a methyl group (CH₃).

Examples of molybdenum-containing precursors for forming molybdenum oxide films (MoOₓ) include bis(tert-butylimino)bis(dimethylamino) molybdenum (C₁₂H₃₀MoN₄), molybdenum pentachloride (MoCl₅), molybdenum dioxide dichloride (MoO₂Cl₂), molybdenum oxytetrachloride (MoOCl₄), and molybdenum hexacarbonyl (Mo(CO)₆).

The term “gap” may generally represent a recess between spacers on a substrate surface.

The term “gapfill” may generally represent a process that fills a gap between spacers with a material.

The term “inhibitor” may generally represent a compound that can be introduced into a processing chamber, that can be deposited nonconformally on a substrate surface, and that inhibits ALD growth of an oxide film. Suitable inhibitors include nitrogen-containing inhibitors, fluorine-containing inhibitors, and carbon-containing inhibitors.

Examples of suitable nitrogen-containing inhibitors may include nitrogen (N₂), ammonia (NH₃), amines, diamines, and aminoalcohols.

Examples of suitable fluorine-containing inhibitors may include F₂, NF₃, and fluorocarbons such as CF₄ or C₂F₆.

Examples of suitable carbon-containing inhibitors may include alkanes, alkenes, alkynes, cyclic hydrocarbons, aromatics, alcohols, aldehydes, esters, ethers, ketones, aldehydes, alkyl halides, alkyl amines, and alkyl diamines. In some examples, the carbon-containing inhibitor may comprise an alkane comprising a general formula CₙH₂ₙ₊₂ in which n=1 to 10. Examples of suitable alkanes may include methane, ethane, propane, butane, pentane, hexane, and substituted alkanes. Other examples of carbon-containing inhibitors may comprise an alkene, an alkyne, a cyclic hydrocarbon, an aromatic, an alcohol, a diol, an aldehyde, an ester, an ether, a ketone, an alkyl halide, an alkyl amine, or an alkyl diamine. In still other examples, the carbon-containing inhibitor may comprise a mixture of carbon-containing inhibitors. Examples of suitable alkenes (CₙH₂ₙ in which n=2 to 10, for an alkene with a single carbon-carbon double bond) may include ethene, propene, and butene. Examples of suitable alkynes (CₙH₂ₙ₋₂ in which n=2 to 10, for an alkyne with a single carbon-carbon triple bond) may include acetylene, propyne, and butyne. Examples of suitable cyclic hydrocarbons may include cyclobutene, cyclopentane and cyclohexane. Examples of suitable aromatics may include benzene, toluene, pyridine, and pyrimidine. Examples of suitable alcohols may include methanol, ethanol, and propanol. Examples of suitable diols may include ethylene glycol, propylene glycol, and hydroquinone. Examples of suitable aldehydes may include formaldehyde and acetaldehyde. Examples of suitable esters may include ethyl formate, methyl acetate, and ethyl acetate. Examples of suitable ethers may include diethyl ether, methyl phenyl ether, and aromatic ethers such as furan. Examples of suitable ketones may include acetone and methyl ethyl ketone. Examples of suitable alkyl halides may include ethyl fluoride, isopropyl bromide, and t-butyl chloride. Examples of suitable alkyl amines may include methylamine, dimethylamine, trimethylamine, and piperidine. Examples of suitable alkyl diamines may include ethylenediamine and 1,3-diaminopropane.

The term “ketone” may generally represent hydrocarbon compounds comprising a non-terminal carbonyl. Ketones have the general formula R—C(O)—R′ where R and R′ are independently an aromatic or aliphatic group. Example ketones comprise acetone and methyl ethyl ketone.

The term “mandrel” may generally represent a raised structure in a patterning process with sidewalls that define locations of spacers. Mandrels may comprise any suitable material. Examples may include polycrystalline silicon, amorphous silicon, silicon oxides, silicon nitrides, and amorphous carbon.

The term “oxidant” may generally represent a gas species containing oxygen available for reacting with a film precursor to form an oxide film. Examples of oxidants comprise molecular oxygen (O₂), water vapor (H₂O), hydrogen peroxide (H₂O₂), and ozone (O₃).

The term “oxide film” may generally represent a film deposited on a substrate surface that comprises oxygen and an oxidized species. Examples of oxide films comprise films of doped or undoped silicon oxide (e.g., silicon dioxide (SiO₂), silicon oxynitride (SiOₓN_{y}, 0≤x≤2, 0≤y≤1.33), silicon oxycarbide (SiCₓO_{2-y}, 0≤x≤1, y=2x)), and metal oxides, such as aluminum oxide (Al₂O₃) hafnium oxide (HfOₓ), titanium oxide (TiOₓ), tungsten oxide (WOₓ), tin oxide (SnOₓ), and molybdenum oxide (MoOₓ).

The term “patterning process” may generally represent a process that is used to generate topography on a substrate.

The term “processing chamber” may generally represent an enclosure in which chemical and/or physical processes are performed on substrates. The pressure, temperature and atmospheric composition within a processing chamber may be controllable to perform chemical and/or physical processes.

The terms “purge” and variants thereof may generally represent processes in which unwanted species are removed from a processing chamber.

The term “spacer” may generally represent a structure formed in a patterning process that define a spacing between features to be formed in a later processing step.

The term “sticking coefficient” may generally represent a ratio of a number of gas-phase species that adsorb to a substrate surface compared to a number of the gas-phase species that impinge on the substrate surface.

The term “substrate” may generally represent any object on which a film can be deposited.

The term “substrate support” may generally represent any structure for supporting a substrate in a processing chamber. Examples comprise chucks, pedestals, and showerhead pedestals used for backside deposition processes.

As mentioned above, atomic layer deposition (ALD) involves performing one or more deposition cycles to grow a thin film on a substrate surface. Example films that may be grown using ALD include various oxide films. PEALD utilizes a plasma to facilitate deposition of a film. During a PEALD oxide film deposition cycle, a film precursor gas is introduced into a processing chamber and adsorbs onto a substrate. Next, the processing chamber is purged to remove excess film precursor. Then, an oxidant is introduced to the processing chamber. A plasma is formed by application of radiofrequency power to electrodes within the processing chamber. The plasma forms reactive oxygen species. The reactive oxygen species react with the film precursor to form a layer of the oxide film. TALD utilizes substrate temperature to drive the chemical reactions that form the oxide film. Examples of oxide films that may be formed by ALD include films of silicon oxynitride (SiOₓN_{y}), silicon dioxide (SiO₂), silicon oxycarbide SiCₓO_{2-y}, aluminum oxide (Al₂O₃), hafnium oxide (HfOₓ), titanium oxide (TiOₓ), tungsten oxide (WOₓ), tin oxide (SnOₓ), and molybdenum oxide (MoOₓ).

ALD may be used to grow an oxide film conformally. However, conformal growth may not be desired in some applications. Accordingly, examples are disclosed that relate to using an inhibitor in an ALD process to deposit oxide film at a relatively greater rate on surfaces at a first depth in a substrate feature compared to surfaces at a second depth, the second depth being deeper in the substrate feature than the first depth. The disclosed examples may provide controllable growth of an oxide film to fill a gap between spacers. This may help to avoid formation of a seam in the oxide film. While described in the context of a PEALD process, the disclosed examples also may be used in other ALD processes. Examples include TALD processes.

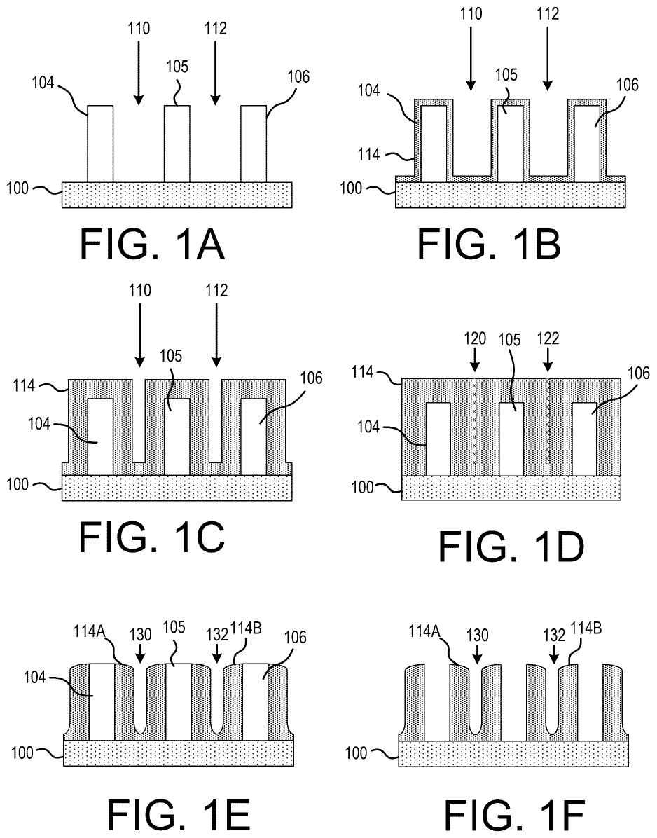

One example of a process in which nonconformal ALD film deposition may be desired is a gapfill process used in patterning. Patterning may generally refer to a sequence of process steps to form a pattern of features on a substrate. FIGS. 1A-1F schematically show structures formed in an example patterning process. In the process of FIGS. 1A-IF, a gap between spacers on a substrate is filled with an oxide film, and then the oxide film is etched. Suitable oxide films may include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

First referring to FIG. 1A, substrate 100 comprises spacers 104, 105, 106 disposed on a top surface of substrate 100. Further, gaps are located between the spacers. For example, gap 110 is located between spacer 104 and spacer 105. Similarly, gap 112 is located between spacer 105 and spacer 106. Spacers 104, 105, 106 may comprise any suitable material. When used in a reverse patterning process, spacers 104, 105, 106 may comprise a sacrificial material which is removed in a subsequent processing step (e.g., a spacer removal process as shown by the sequence of structures of FIGS. 1D-1F).

In an ALD oxide gapfill process, film precursor gas diffuses into a gap and adsorbs onto substrate surfaces within the gap. The adsorbed film precursor is reacted with an oxidant to form an oxide film on the surfaces within the gap. FIG. 1B schematically shows an oxide film 114 on substrate 100. Oxide film 114 is formed using one or more ALD cycles. As a result, oxide film 114 is deposited conformally on surfaces within gap 110 and gap 112 and over spacers 104, 105, 106. Oxide film 114 may comprise any suitable material. Examples include one or more of silicon dioxide, silicon oxynitride, silicon oxycarbide, aluminum oxide, hafnium oxide, titanium oxide, tungsten oxide, tin oxide, or molybdenum oxide. ALD cycles can be repeated to progressively fill gap 110 and gap 112 with a conformal film. FIG. 1C shows further conformal deposition of oxide film 114 resulting from additional ALD cycles. As shown in FIG. 1C, conformal growth of oxide film 114 leads to narrowing of gap 110 and gap 112.

However, deposition of an oxide film by ALD in a gapfill process may result in formation of a seam in oxide film 114. FIG. 1D shows a seam 120 that has formed in gap 110. Likewise, seam 122 comprises gap 112. Oxide materials may comprise terminal OH groups in seams. Terminal OH groups limit crosslinking. Further, oxide material within seams may be low density. Such properties can cause problems during etching. FIG. 1E schematically shows the result of etching substrate 100 to expose spacers 104, 105, 106. Etching oxide film 114 leaves oxide film portion 114A between spacers 104 and 105 and oxide film portion 114B between spacers 105 and 106. However, due to low density and terminal OH groups within the seam, the material at the seam may be etched at a faster rate compared to etch rates at other locations. Terminal OH groups may limit forming oxygen bridging bonds within the seam. As such, etching to expose spacers 104, 105, 106 also etches seams 120, 122. As a result, holes 130, 132 are formed in remaining film portions 114A, 114B, respectively. Holes 130, 132 degrade the pattern formed by oxide film 114. FIG. 1F shows the result of further processing of substrate 100 to remove spacers 104, 105, 106. The remaining film portions 114A, 114B of oxide film 114 are relatively thin due to holes 130, 132, respectively. This may lead to pattern collapse and/or a missed pattern after transfer. Additionally, further processing may lead to further etching of the film portions 114A, 114B within holes 130, 132 to expose substrate 100. This may be referred to as “punchthrough”.

As pitch sizes decrease, a seam may be a greater proportion of a deposited feature. Etching into a seam may significantly degrade the oxide film. As such, seams may pose greater challenges at smaller pitches.

One possible solution to the problem posed by seams in an oxide film is to utilize a different ALD gapfill material, such as a nitride. However, nitrides and other possible gapfill materials also may have terminal OH groups and/or low densities in seams.

Accordingly, examples are disclosed that relate to using an inhibitor during an ALD process to cause an oxide film to grow nonconformally. Briefly, an inhibitor may be introduced during ALD processing to deposit the inhibitor nonconformally on a substrate comprising a gap between spacers. The substrate is exposed to the inhibitor under conditions that cause a concentration of inhibitor deposited at a first depth within the gap to be greater than a concentration of inhibitor deposited at a second depth within the gap, the second depth being deeper in the gap than the first depth. Film growth may be more strongly inhibited on surfaces with a relatively greater concentration of inhibitor compared to surfaces with a relatively lesser concentration of inhibitor. Thus, film growth on the surfaces at the first depth may be more strongly inhibited than on the surfaces deeper within the gap. This may allow the oxide film to fill the gap in a bottom-up manner without pinching off at locations closer to the gap opening. Such growth may help to avoid formation of voids. Further, as the oxide film grows, the oxide film may develop an angled profile rather than a vertical profile. This may help avoid seam formation within the gap. Avoiding seam formation may help avoid problems such as punchthrough, pattern collapse, and missed pattern after transfer. Avoiding such problems may help preserve patterns in various patterning processes. As seams may comprise a greater proportion of a deposited feature at smaller pitches, by avoiding seam formation, the disclosed examples may help enable patterning applications for smaller pitches.

An inhibitor may be introduced into a processing chamber in any suitable manner during an ALD process. In some examples, an inhibitor may be deposited on the substrate by forming a plasma comprising the inhibitor. In such examples, the plasma comprising the inhibitor may be used to deposit inhibitor prior to introduction of a film precursor. In other examples, an inhibitor may be introduced into the processing chamber together with one or more other processing gases. Examples include one or more of a film precursor, an oxidant, or an inert gas. In some examples, nonconformal adsorption of an inhibitor may be dependent on processing conditions such as total processing chamber pressure, partial pressure of the inhibitor, partial pressure of other gases, substrate temperature, gas flow rates, inhibitor gas flow duration, and plasma characteristics. For example, the use of a capacitively coupled plasma or inductively coupled plasma may lead to directionality of ion bombardment on a substrate surface. The directionality may deposit a greater concentration of inhibitor in an upper region of a gap and on surfaces surrounding the gap than deeper within the gap. In some examples, a relatively lower partial pressure of the inhibitor is used for relatively lower aspect ratios of gaps, and a relatively higher partial pressure of the inhibitor is used for relatively higher aspect ratios.

The inhibitor may chemisorb and/or physisorb to the substrate surface in various examples. Chemisorption of the inhibitor may comprise covalent, ionic, and/or hydrogen bonding between the inhibitor and surface atoms. Physisorption may comprise van der Waals attraction between the inhibitor and surface atoms. Further, the inhibitor may be converted to other species that adsorb to the substrate surface by the processing environment. For example, a fluorine-containing inhibitor may form reactive fluorine species such as radicals and ions (e.g. fluorine anions) in a plasma. The reactive fluorine species then may adsorb to the substrate surface.

Any suitable inhibitor may be used in an oxide gapfill process according to the disclosed examples. In some examples, a nitrogen-containing inhibitor can be used. Nitrogen-containing inhibitors can chemisorb to a substrate surface. Example nitrogen-containing inhibitors may include nitrogen (N₂), ammonia (NH₃), amines, diamines, and aminoalcohols. Suitable amines may include methylamine, dimethylamine, trimethylamine, and triethylamine. Suitable aminoalcohols may include 1-amino-2-ethanol.

In some examples, a plasma may be used to deposit the nitrogen-containing inhibitor. In some such examples, a nitrogen-containing inhibitor can be used to form a densifying plasma to densify an oxide film. For example, in a PEALD oxide deposition process, a plasma may be used to deposit the nitrogen-containing inhibitor. This may result in formation of an oxynitride film on at least some portions of the substrate. Example oxynitride films comprise silicon oxynitride films. Such oxynitride films may offer additional etch resistance and help protect a pattern during subsequent etching steps.

In some examples, a fluorine-containing inhibitor alternatively or additionally may be used. Fluorine-containing inhibitors also may chemisorb to surfaces in gaps. Fluorine-containing inhibitors may be deposited using a plasma comprising the fluorine-containing inhibitor. Example fluorine-containing inhibitors include molecular fluorine (F₂), nitrogen trifluoride (NF₃), and fluorocarbons (e.g., carbon tetrachloride (CF₄), hexafluoroethane (C₂F₆)). In some examples, an ALD process with a fluorine-containing inhibitor may be performed at relatively higher temperatures. Relatively higher temperatures may be used to avoid incorporation of fluorine into the oxide film that is being deposited. In some examples, a temperature of 400° C. or greater may be used. However, in other examples, any other suitable temperature may be used, including temperatures outside of this range.

Further, in other examples, a carbon-containing inhibitor alternatively or additionally may be used. A carbon-containing inhibitor may physisorb to a substrate, and inhibit oxide-film growth by competing with a film precursor for oxidant. As the oxidant is at least partially consumed by the carbon-containing inhibitor, the oxidant is less available for reacting with adsorbed film precursor.

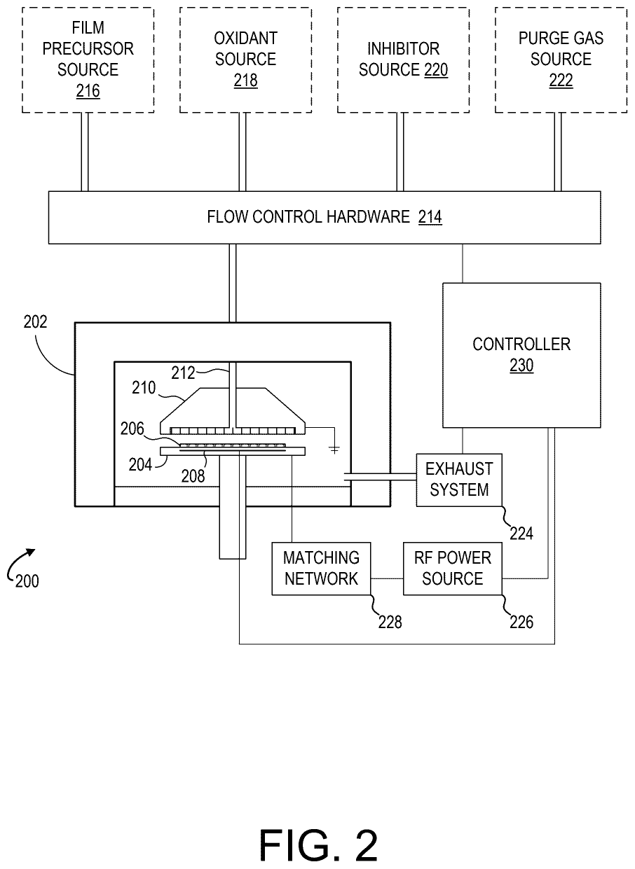

Prior to discussing these examples in more detail, FIG. 2 shows a schematic view of an example ALD tool 200 for performing atomic layer deposition using an inhibitor. ALD tool 200 is configured as a PEALD tool. However, as mentioned above, the use of an inhibitor as disclosed herein also may be used to vary the conformality of a film deposited in other types of tools. Examples may include TALD and/or other ALD tools.

ALD tool 200 comprises a processing chamber 202 and a substrate support 204 within the processing chamber. Substrate support 204 is configured to support a substrate 206 disposed within processing chamber 202. Substrate support 204 may comprise a pedestal, a chuck, and/or any other suitable structure. Processing chamber 202 further may include a substrate heater 208. In other examples, a heater may be omitted, or may be located elsewhere within processing chamber 202.

ALD tool 200 further comprises a showerhead 210, a gas inlet 212, and flow control hardware 214. In other examples, a processing tool may comprise a nozzle or other apparatus for introducing gas into processing chamber 202, as opposed to or in addition to a showerhead. Flow control hardware 214 is connected to a film precursor gas source 216, an oxidant source 218, an inhibitor source 220, and a purge gas source 222.

Film precursor gas source 216 may comprise any suitable film precursor that, when reacted with the oxidant, forms an oxide film. Example silicon-containing oxide films include silicon dioxide, silicon oxynitride, and silicon oxycarbide. Example metal oxide films include aluminum oxide, hafnium oxide, titanium oxide, tungsten oxide, tin oxide, and molybdenum oxide. Example film precursors for silicon-containing oxide films may include polysilanes, aminosilanes, halosilanes, and organosilanes. Example film precursors for forming metal oxide films may include AlCl₃, Al(CH₃)₃, Al(OC₂H₅)₃, Al(N(CH₃)₂)₃, HfCl₄, Hf(N(C₂H₅)₂)₄, Hf(OC(CH₃)₃)₄, TiCl₄, Ti(OCH(CH₃)₂)₄, WF₆, WCl₆, W(CO)₆, bis(tert-butylimino) bis(dimethylamino) tungsten (C₁₂H₃₀N₄W), SnCl₄, (CH₃)+Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂, MoOCl₄, bis(tert-butylimino)bis(dimethylamino) molybdenum (C₁₂H₃₀MoN₄), and Mo(CO)₆. Oxidant source 218 may comprise, for example, O₂, O₃, water vapor, hydrogen peroxide, or a mixture of two or more thereof.

Inhibitor source 220 comprises any suitable inhibitor that can be deposited nonconformally on a substrate and inhibit growth of an oxide film in an ALD process. Suitable inhibitors may include nitrogen-containing inhibitors, fluorine-containing inhibitors, and carbon-containing inhibitors. Suitable nitrogen-containing inhibitors may include nitrogen (N₂), ammonia (NH₃), amines, diamines, and aminoalcohols. Suitable fluorine-containing inhibitors may include F₂, NF₃, and fluorocarbons that are in gas phase under processing conditions.

Suitable carbon-containing inhibitors may include compounds that can be oxidized by the oxidant to form gas-phase products, and that adsorb nonconformally to a substrate surface. Example carbon-containing inhibitors suitable for use for nonconformal film deposition may comprise various alkanes, alkenes, alkynes, cyclic hydrocarbons, aromatics, alcohols, aldehydes, esters, ethers, ketones, aldehydes, alkyl halides, alkyl amines, and alkyl diamines. More specific examples of carbon-containing inhibitors include those listed above.

Purge gas source 222 may comprise any suitable inert gas. Examples include helium, neon, argon, krypton, xenon, and nitrogen. In some examples, one or more additional purge gas sources may be included, each providing a different purge gas.

Flow control hardware 214 may be controlled to flow gas from film precursor source 216, oxidant source 218, inhibitor source 220, and purge gas source 222 into processing chamber 202 via gas inlet 212. Flow control hardware 214 may comprise one or more valves controllable to place a selected gas source or selected gas sources in fluid connection with gas inlet 212.

ALD tool 200 further comprises an exhaust system 224. Exhaust system 224 is configured to receive gases outflowing from processing chamber 202. In some examples, exhaust system 224 is configured to actively remove gas from processing chamber 202 and/or apply a partial vacuum. Exhaust system 224 may comprise any suitable hardware, including one or pumps.

ALD tool 200 further comprises a radiofrequency (RF) power source 226 that is electrically connected to substrate support 204. Radiofrequency power source 226 is configured to form a plasma. When reacting adsorbed film precursor with an oxidant, radiofrequency power source 226 may form a plasma comprising the oxidant. In some examples, a nitrogen-containing inhibitor or fluorine-containing inhibitor is deposited on a substrate by forming a plasma comprising the inhibitor. As such, radiofrequency power source 226 also may be used to form a plasma comprising an inhibitor. Showerhead 210 is configured as a grounded opposing electrode in this example. In other examples, radiofrequency power source 226 may supply radiofrequency power to showerhead 210, or to other suitable electrode structure. ALD tool 200 may include a matching network 228 for impedance matching of the radiofrequency power source 226. Radiofrequency power source 226 may be configured for any suitable frequency and power. Examples of suitable frequencies include 400 kHz and 13.56 MHz. Examples of suitable powers include powers between 0 and 6500 watts. In some examples, radiofrequency power source 226 is configured to operate at a plurality of different frequencies and/or powers.

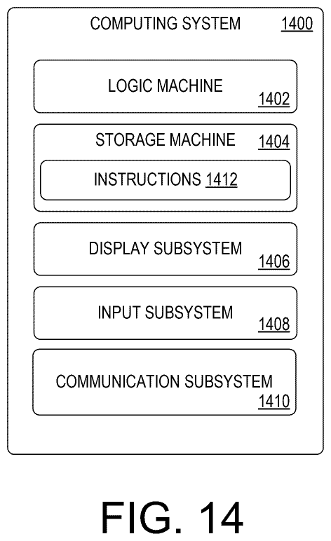

Controller 230 is operatively coupled to substrate heater 208, flow control hardware 214, exhaust system 224, and radiofrequency power source 226. Controller 230 is configured to control various functions of ALD tool 200 to perform a thin film deposition process, such as an ALD process. For example, controller 230 is configured to operate substrate heater 208 to heat a substrate to a desired temperature. Controller 230 is also configured to operate flow control hardware 214 to flow a selected gas or mixture of gases at a selected rate into processing chamber 202. Controller 230 is further configured to operate exhaust system 224 to remove gases from processing chamber 202. Controller 230 may, for example, control exhaust system 224 and/or flow control hardware 214 to purge processing chamber 202. Furthermore, controller 230 is configured to operate radiofrequency power source 226 to form a plasma comprising the oxidant or form a plasma comprising an inhibitor, as well as to control any other suitable functions of ALD tool 200. Controller 230 may comprise any suitable computing system. Example computing systems are described below with reference to FIG. 14.

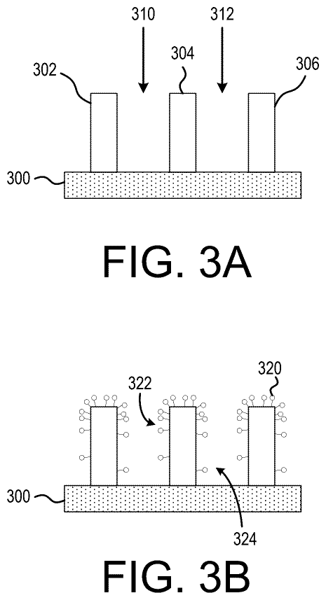

As mentioned above, an inhibitor may be used in an ALD oxide deposition process for gapfill to avoid forming a seam. The inhibitor may deposit nonconformally on the substrate surface as a function of depth within the gap by controlling processing conditions used to deposit the inhibitor. FIGS. 3A-3B show an example of adsorption of an inhibitor onto a substrate 300. Substrate 300 comprises spacers 302, 304, 306 and gaps 310, 312 between the spacers. FIG. 3B schematically shows chemisorption of the inhibitor. The inhibitor may replace hydroxyl groups on the surface with a functional group 320. Functional group 320 may comprise any suitable functional group. In some examples, the functional group 320 comprises an amino group. In other examples, the functional group 320 comprises a fluoro group. Conditions are controlled to cause a greater concentration of inhibitor to deposit at a first depth within the gaps 310, 312. This is indicated at first depth 322 by a greater concentration of functional groups 320. Additionally, a lesser concentration of inhibitor is deposited at a second depth within the gaps 310, 312. This is indicated at second depth 324 by a lesser concentration of functional groups 320. The terms “greater concentration” and “lesser concentration” are relative to each other. The second depth 324 is deeper within the gap than the first depth 322. As oxide film-forming reactions nucleate at a slower rate on inhibited surfaces, oxide film growth may be slowed. Thus, an oxide film growth rate may be slower at first depth 322 compared to a growth rate at second depth 324. As discussed above, a plasma comprising the inhibitor may be used to deposit the inhibitor. In other examples, such as where a carbon-containing inhibitor is used, inhibitor may physisorb to a substrate surface. In such examples, a greater concentration of inhibitor may physisorb at first depth 322 within gaps 310, 312 than at second depth 324 within gaps 310, 312.

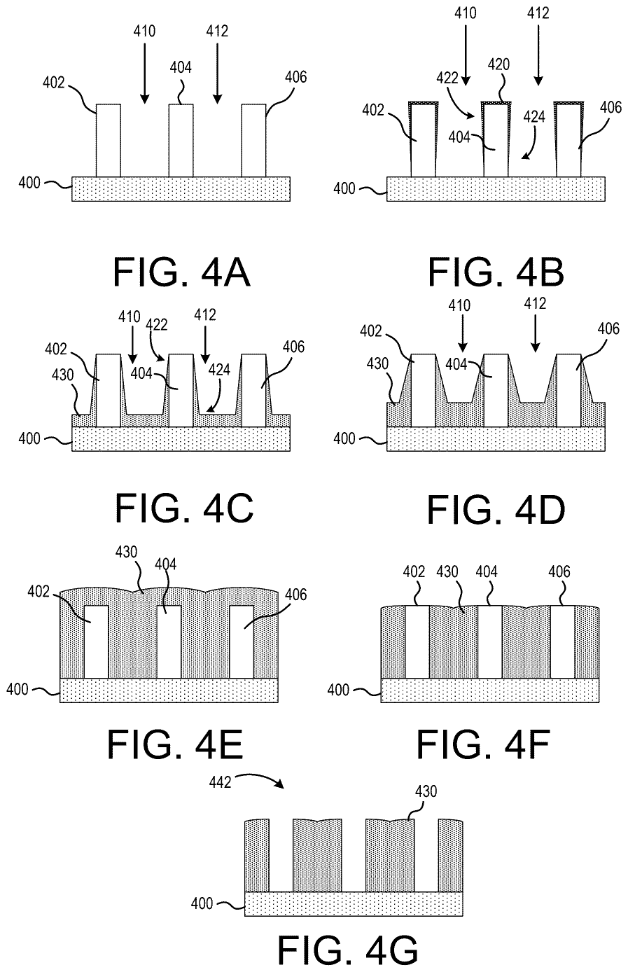

FIGS. 4A-4G schematically show example structures formed in a patterning process comprising an ALD gapfill process utilizing an inhibitor to avoid seam formation. First, FIG. 4A shows a substrate 400 comprising spacers 402, 404, 406 and gaps 410, 412 between the spacers. Spacers 402, 404, 406 may be formed using any suitable patterning method.

As shown in FIG. 4B, an inhibitor 420 is deposited onto surfaces of the spacers and/or gap. A concentration of inhibitor 420 deposited at a first depth 422 within gaps 410, 412 is greater than a concentration of inhibitor 420 deposited at a second depth 424 within gaps 410, 412. The second depth 424 is deeper within the gaps than the first depth 422. Any suitable processing conditions may be controlled to achieve the nonconformal deposition of inhibitor 420. For example, a relatively higher frequency RF power (“HF RF power”) may favor inhibitor adsorption at first depth 422 within gaps 410, 412 compared to inhibitor adsorption at second depth 424. Likewise, a relatively lower frequency RF power (“LF RF power”) component may be used in a plasma to achieve nonconformal deposition of inhibitor 420. Inhibitor 420 may comprise any suitable inhibitor. Example inhibitors include nitrogen-containing inhibitors, fluorine-containing inhibitors, and carbon-containing inhibitors. Suitable nitrogen-containing inhibitors include N₂, NH₃, amines, diamines, and aminoalcohols. Suitable fluorine-containing inhibitors include F₂, NF₃, and fluorocarbons. Suitable carbon-containing inhibitors include alkanes, alkenes, alkynes, cyclic hydrocarbons, aromatics, alcohols, aldehydes, esters, ethers, ketones, aldehydes, alkyl halides, alkyl amines, and alkyl diamines. Nitrogen-containing inhibitors and fluorine-containing inhibitors may be deposited using a plasma, as described above. Inhibitors may physisorb and/or chemisorb in various examples. Some example inhibitors are described above.

FIG. 4C schematically shows growth of an oxide film 430 on substrate 400. The deposited inhibitor 420 of FIG. 4B is omitted from FIG. 4C for clarity. Oxide film 430 may be formed by performing one or more ALD cycles with an inhibitor. Example ALD cycles are described in more detail below. Example silicon-containing oxide films include silicon dioxide, silicon oxynitride, and silicon oxycarbide. Example metal oxide films include aluminum oxide, hafnium oxide, titanium oxide, tungsten oxide, tin oxide, and molybdenum oxide. As described above, oxide film growth may be relatively slower on surfaces with a greater concentration of deposited inhibitor and relatively faster on surface with a lesser concentration of deposited inhibitor. Thus, as depicted in FIG. 4C, oxide film 430 growth is relatively slower at the first depth 422 within gaps 410, 412 and relatively faster at the second depth 424 within gaps 410, 412.

FIG. 4D schematically shows further growth of oxide film 430. Oxide film 430 continues to grow at a higher rate deeper within gaps 410, 412 than at lesser depths. The resulting profile of oxide film 430 may help avoid formation of a seam or a void. In contrast, oxide film 114 of FIG. 1B-1C has relatively vertical surfaces within gaps 110, 112 which can lead to seam formation, as shown in FIG. 1D.

FIG. 4E shows additional growth of oxide film 430 to completely fill gaps 410, 412. Additional oxide film is deposited on top of spacers, 402, 404, 406. The additional oxide film may be referred to as overburden. Due to the use of an inhibitor, oxide film 430 fills gaps 410, 412 in a bottom-up manner with no seam formation.

Next, FIG. 4F shows substrate 400 after performing an etch on oxide film 430 to expose spacers 402, 404, 406. As oxide film 430 lacks seams, the etching process does not form holes in the oxide film as depicted in FIG. 1F.

Continuing, a spacer removal is performed to remove spacers 402, 404, 406 and form a pattern 452, as shown in FIG. 4G. The spacer removal may comprise a dry etch, a wet etch, or other suitable method to remove spacers. After etching, the remaining portions of oxide film 430 are do not have holes such as those shown in FIG. 1F. As such, the pattern 452 formed by oxide film 430 is preserved. Thus, in contrast to the example depicted in FIGS. 1A-1D and 2A-2C, the use of an inhibitor in an ALD process to fill a gap between spacers may help avoid seam formation and pattern collapse.

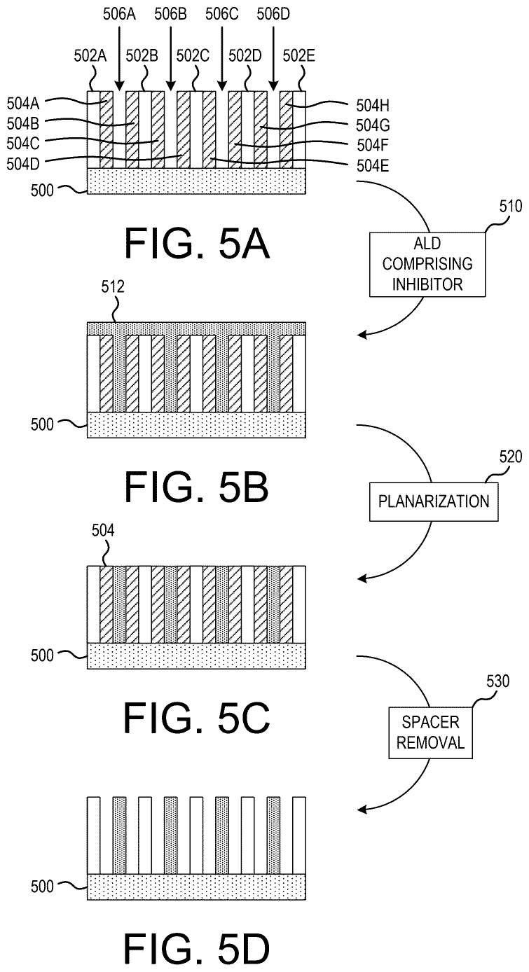

FIGS. 5A-5D schematically show another example patterning process that uses ALD comprising an inhibitor. As shown in FIG. 5A, substrate 500 comprises a plurality of mandrels 502A-E and a plurality of spacers 504A-H. Spacers 504A-H may be formed on mandrels 502A-E by a spacer deposition step (e.g. using ALD) followed by an etch step. Spacers 504A-H may comprise any suitable material. Examples include amorphous carbon, amorphous silicon, silicon dioxide, and titanium nitride. Substrate 500 further comprises gaps 506A-D between spacers 504A-H. Gaps 506A-D may comprise any suitable aspect ratio(s). Examples include aspect ratios in a range of 5:1 to 30:1. As mentioned above, in examples with gaps comprising a relatively higher aspect ratio, processing conditions may be adjusted to use a relatively higher partial pressure of the inhibitor. Likewise, in examples with gaps comprising a relatively lower aspect ratio, processing conditions may be adjusted to use a relatively lower partial pressure of the inhibitor.

Gaps 506A-D may be filled with an oxide film by utilizing ALD comprising an inhibitor, as indicated at 510. FIG. 5B shows oxide film 512 deposited on substrate 500 to fill gaps 506A-D with overburden. Numbers for spacers, gaps, and mandrels are omitted from FIGS. 5B-D for clarity. Oxide film 512 may comprise any suitable material. Example silicon-containing oxide films include silicon dioxide, silicon oxynitride, and silicon oxycarbide. Example metal oxide films include aluminum oxide, hafnium oxide, titanium oxide, tungsten oxide, tin oxide, and molybdenum oxide. Due to the use of an inhibitor in ALD processing, gaps 506A-D are filled without seam formation. In the depicted example, a planarization step 520 is performed to expose spacers 504, as shown in FIG. 5C. FIG. 5D shows the result of a spacer removal 530 performed to remove spacers 504. Spacer removal 530 may be performed using any suitable method, such as a wet etch or dry etch. As no seams are formed during ALD gapfill 510, issues such as punchthrough and pattern collapse may be avoided during spacer removal 530.

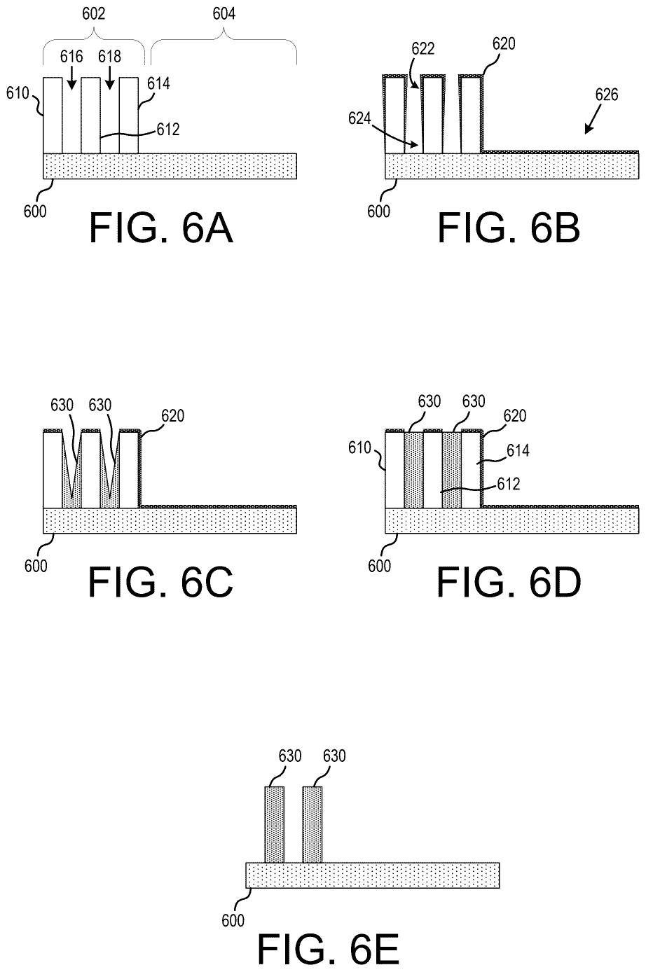

ALD processing with an inhibitor also may be used to selectively deposit oxide film on some substrate regions while avoiding film deposition on other substrate regions. FIGS. 6A-6E schematically show an example patterning process on a substrate 600 comprising a feature-dense region 602 and an expanse 604. As shown in FIG. 6A, feature-dense region 602 comprises spacers 610, 612, 614 and gaps 616, 618 between the spacers. In contrast, expanse 604 lacks features. The patterning process includes performing ALD with an inhibitor to selectively deposit oxide film in gaps of the feature-dense region 602.

FIG. 6B schematically shows deposition of inhibitor 620 on substrate 600. At feature-dense region 602, a concentration of inhibitor 620 deposited at a first depth 622 within gaps 616, 618 is greater than a concentration of inhibitor 620 deposited at a second depth 624 within gaps 616, 618. The second depth 624 is deeper in the gaps than the first depth 622. At expanse 604, inhibitor 620 is deposited evenly over the substrate surface 626. Inhibitor 620 may comprise any suitable inhibitor. Examples include nitrogen-containing inhibitors, fluorine-containing inhibitors, and carbon-containing inhibitors. Example inhibitors are described in more detail above.

FIG. 6C shows an oxide film 630 deposited on substrate 600. Oxide film 630 may comprise any suitable material. Example silicon-containing oxide films include silicon dioxide, silicon oxynitride, and silicon oxycarbide. Example metal oxide films include aluminum oxide, hafnium oxide, titanium oxide, tungsten oxide, tin oxide, and molybdenum oxide. Oxide film 630 may be formed by performing repeated ALD cycles where at least some ALD cycles include introduction of inhibitor 620. Inhibitor 620 inhibits oxide film growth. Further, the inhibition effect is greater where there is a greater concentration of deposited inhibitor. As depicted in FIG. 6C, oxide film 630 grows relatively faster at the second depth 624 within gaps 616, 618 corresponding to a relatively lesser concentration of inhibitor 620 than at the first depth 622 within gaps 616, 618. Oxide film 630 grows relatively slower at the first depth 622 within gaps 616, 618 corresponding to a relatively greater concentration of inhibitor 620 than at the second depth 624 within gaps 616, 618. As such, oxide film 630 may grow with an angled profile in the gaps, which helps avoid seam formation.

FIG. 6D schematically shows further growth of oxide film 630 to fill gaps 616, 618. As film growth is selectively inhibited at first depth 622 within the gaps, oxide film 630 may fill gaps 616, 618 in a bottom-up manner. Additionally, oxide film 630 forms without seams. Furthermore, oxide film 630 does not grow on expanse 604 due to inhibitor 620. As such, performing ALD with an inhibitor may help form oxide film in gaps between spacers of the feature-dense region 602 while avoiding oxide film formation on the expanse 604.

After filling gaps 616, 618, an optional planarization step may be performed to expose spacers 610, 612, 614. However, as inhibitor 620 may inhibit oxide film growth on top of spacers 610, 612, 614, in some examples the spacers may be exposed for spacer removal without planarization. Furthermore, as oxide film growth is inhibited on expanse 604, planarization is not needed to remove oxide film from expanse 604. Thus, in some examples, a planarization step may be avoided due to the use of inhibitor in ALD gapfill. In some examples, a passivation step may be performed to remove excess inhibitor.

FIG. 6E shows substrate 600 following a spacer removal step. As a result, portions of oxide film 630 remain in feature-dense region 602. Oxide film is not formed on expanse 604.

As mentioned above, ALD processing may comprise a plurality of ALD cycles, such as tens of cycles, to deposit an oxide film on a substrate. Some ALD cycles may comprise depositing an inhibitor. Other ALD cycles may omit depositing an inhibitor. However, inhibitor may remain on a substrate to inhibit film growth from such cycles.

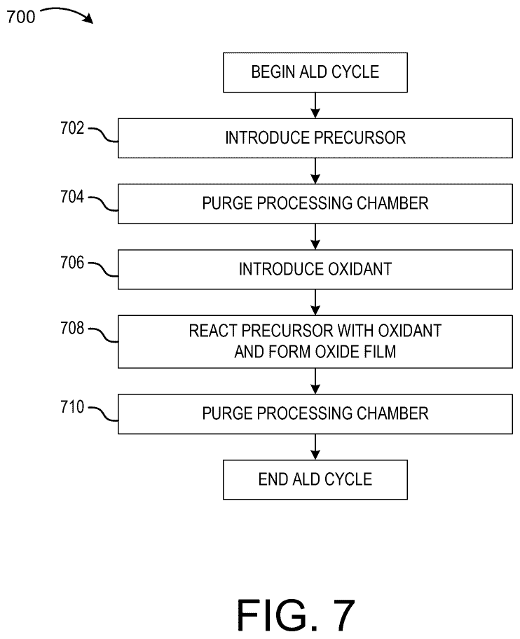

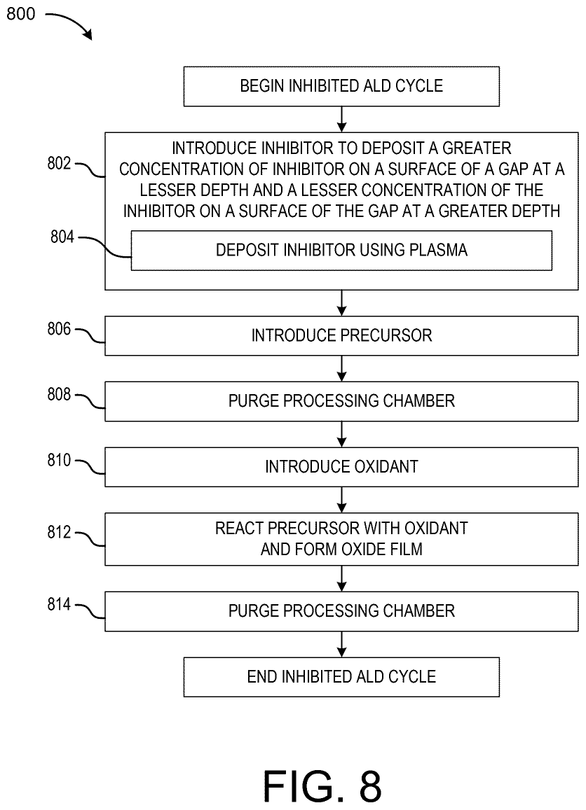

FIG. 7 shows an example ALD cycle 700 that omits introducing an inhibitor. FIG. 8 shows a flow diagram of an example ALD cycle 800 comprising introduction of an inhibitor. To fill a gap using ALD processing, a plurality of ALD cycles are performed where at least one ALD cycle comprises an ALD cycle comprising an inhibitor. In some examples, each ALD cycle comprises introduction of an inhibitor. In other examples, an inhibitor may be introduced in some, but not all ALD cycles. ALD cycles comprising introduction of an inhibitor and ALD cycles that omit an inhibitor may be performed in any suitable order.

First, FIG. 7 shows a flow diagram of an example ALD cycle 700. ALD cycle 700 omits introduction of an inhibitor. ALD cycle 800 may be performed any suitable number of times to form an oxide film on a substrate disposed in a processing chamber of an ALD tool. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films. ALD tool 200 is an example tool for performing ALD cycle 700. At 702, ALD cycle 700 comprises introducing a film precursor into a processing chamber. Suitable film precursors for silicon-containing oxide films may include polysilanes, aminosilanes, halosilanes, and organosilanes. Suitable film precursors for forming metal oxide films may include AlCl₃, Al(CH₃)₃, Al(OC₂H₅)₃, Al(N(CH₃)₂)₃, HfCl₄, Hf(N(C₂H₅)₂)₄, Hf(OC(CH₃)₃)₄, TiCl₄, Ti(OCH(CH₃)₂)₄, WF₆, WCl₆, W(CO)₆, C₁₂H₃₀N₄W, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂. MoOCl₄, C₁₂H₃₀MoN₄, and Mo(CO)₆. At 704, the processing chamber is purged to remove excess film precursor. In some examples, an inert gas may be flowed into the processing chamber during a purge.

Continuing, at 706, ALD cycle 700 comprises introducing an oxidant into the processing chamber. Any suitable oxidant that can react with the film precursor to form an oxide film can be used. Suitable oxidants include O₂, O₃, H₂O, and H₂O₂.

At 708, ALD cycle 700 comprises reacting the film precursor with the oxidant to form a layer of oxide film on the substrate. In examples that involve PEALD, a plasma may be used to react the film precursor with the oxidant. For example, the reaction can be performed using a radiofrequency power source to form a plasma comprising the oxidant. The radiofrequency power source may be operated at any suitable frequency (e.g., 400 kHz, 13.56 MHz in some examples) and power (e.g., between 0 and 7000 watts in some examples). The oxidant can be converted to oxygen-containing reactive species via the plasma. The oxygen-containing reactive species can then react with the adsorbed monolayer of film precursor to form a layer of oxide film on the substrate. In some examples, a purge 710 is performed following 708 to complete the ALD cycle. When a radiofrequency power source is used to form a plasma, the purge may be performed after extinguishing the plasma. In other examples, a purge may be omitted. Further, in some examples, the substrate is heated via a substrate heater during processing. In other examples, an ALD cycle may be performed using TALD. In such examples, the reaction at may be performed using thermal energy.

FIG. 8 shows an example ALD cycle comprising an inhibitor 800. ALD cycle comprising an inhibitor 800 may be performed by an ALD tool comprising a processing chamber in which the substrate is disposed. ALD cycle comprising an inhibitor 800 comprises, at 802, introducing an inhibitor into the processing chamber. The inhibitor introduction is controlled to deposit a greater amount of inhibitor at a surface of the gap at a first depth and a lesser amount of inhibitor at a surface of the gap at a second depth, the second depth being deeper in the gap than the first depth. Any suitable inhibitor may be used. Examples include a nitrogen-containing inhibitor, a fluorine-containing inhibitor, or a carbon-containing inhibitor. Suitable nitrogen-containing inhibitors include N₂, NH₃, amines, diamines, and aminoalcohols. Suitable fluorine-containing inhibitors include F₂, NF₃, and fluorocarbons. Suitable carbon-containing inhibitors include alkanes, alkenes, alkynes, cyclic hydrocarbons, aromatics, alcohols, aldehydes, esters, ethers, ketones, aldehydes, alkyl halides, alkyl amines, and alkyl diamines.

In some examples, as indicated at 804, introducing the inhibitor comprises forming a plasma to deposit the inhibitor. For example, the ALD tool may control a radiofrequency power source to form a plasma comprising the inhibitor. Suitable inhibitors for plasma deposition include nitrogen-containing inhibitors and fluorine-containing inhibitors. The radiofrequency power source may be operated at any suitable frequency (e.g., 400 kHz, 13.56 MHz) and power (e.g., between 0 and 7000 watts). The inhibitor may be converted to a reactive species by the plasma which may help chemisorption of the inhibitor. For example, nitrogen-containing reactive species created by the plasma may form a nitride surface upon deposition. Similarly, fluorine-containing reactive species may form a fluoride surface. In other examples, the inhibitor is deposited without a plasma. Examples of inhibitors that may be deposited without a plasma may include carbon-containing inhibitors, such as those described above.

At 806, inhibited ALD cycle 800 comprises introducing a film precursor into a processing chamber. Suitable film precursors for silicon-containing oxide films may include polysilanes, aminosilanes, halosilanes, and organosilanes. Suitable film precursors for forming metal oxide films may include AlCl₃, Al(CH₃)₃, Al(OC₂H₅)₃, Al(N(CH₃)₂)₃, HfCl₄, Hf(N(C₂H₅)₂)₄, Hf(OC(CH₃)₃)₄, TiCl₄, Ti(OCH(CH₃)₂)₄, WF₆, WCl₆, W(CO)₆, C₁₂H₃₀N₄W, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂. MoOCl₄, C₁₂H₃₀MoN₄, and Mo(CO)₆. At 808, the processing chamber is purged to remove excess film precursor.

ALD cycle comprising an inhibitor 800 further comprises introducing an oxidant into the processing chamber at 810. Suitable oxidants include O₂, O₃, H₂O, and H₂O₂. At 812, inhibited ALD cycle 800 comprises reacting the film precursor with the oxidant to form a layer of oxide film on the substrate. In examples that involve PEALD, a plasma may be used to react the film precursor with the oxidant. For example, the reaction can be performed using a radiofrequency power source to form a plasma comprising the oxidant. The radiofrequency power source may be operated at any suitable frequency (e.g., 400 kHz, 13.56 MHz) and power (e.g., between 0 and 7000 watts). The oxidant can be converted to oxygen-containing reactive species via the plasma. The oxygen-containing reactive species can then react with the adsorbed monolayer of film precursor to form a layer of oxide film on the substrate. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films. Due to the inhibitor deposited at 802, the oxide film grows nonconformally. As such, a relatively thicker oxide film layer may be formed on a surface in the gap at the second depth corresponding to the lesser concentration of inhibitor. Likewise, a relatively thinner oxide film layer may be formed on a surface in the gap at the first depth corresponding to the greater concentration of inhibitor.

After reacting the film precursor with the oxidant, inhibited ALD cycle 800 comprises purging the processing chamber at 814 to complete the inhibited ALD cycle 800. In some examples, a purge may be omitted.

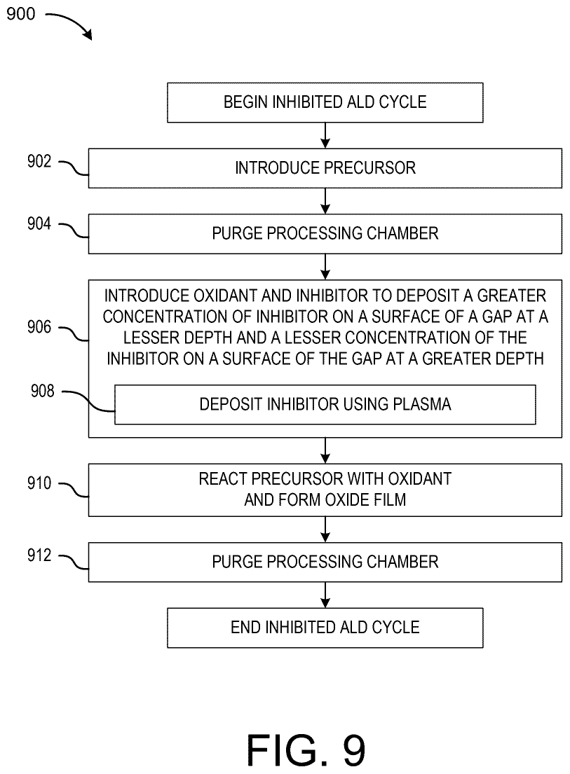

FIG. 9 shows a flow diagram for another example ALD cycle comprising an inhibitor 900 in which the inhibitor is introduced with the oxidant. ALD cycle comprising an inhibitor 900 may be used to deposit an oxide film on a substrate comprising a gap between spacers. ALD cycle comprising an inhibitor 900 may be performed by an ALD tool comprising a processing chamber in which the substrate is disposed.

ALD cycle comprising an inhibitor 900 comprises, at 902, introducing a film precursor into a processing chamber. Suitable film precursors for silicon-containing oxide films may include polysilanes, aminosilanes, halosilanes, and organosilanes. Suitable film precursors for forming metal oxide films may include AlCl₃, Al(CH₃)₃, Al(OC₂H₅)₃, Al(N(CH₃)₂)₃, HfCl₄, Hf(N(C₂H₅)₂)₄, Hf(OC(CH₃)₃)₄, TiCl₄, Ti(OCH(CH₃)₂)₄, WF₆, WCl₆, W(CO)₆, C₁₂H₃₀N₄W, SnCl₄, (CH₃)₄Sn, (C₂H₅)₄Sn, (CH₃)₂SnCl₂, Bu₂Sn(OMe)₂, Sn(NMe₂)₄, Me₂Sn(NMe₂)₂, Me₃Sn(NMe₂), MoCl₅, MoO₂Cl₂. MoOCl₄, C₁₂H₃₀MoN₄, and Mo(CO)₆. At 904, the processing chamber is purged to remove excess film precursor.

ALD cycle comprising an inhibitor 900 further comprises introducing an oxidant and an inhibitor into the processing chamber at 906. Suitable oxidants include O₂, O₃, H₂O, and H₂O₂. The inhibitor introduced at 906 deposits into the gap such that a concentration of inhibitor at a first depth within the gap is greater than a concentration of inhibitor at a second depth within the gap, the second depth being deeper in the gap than the first depth. Any suitable inhibitor may be used, such as a nitrogen-containing inhibitor, a fluorine-containing inhibitor, or a carbon-containing inhibitor as described above.

At 910, ALD cycle comprising an inhibitor 900 comprises reacting the film precursor with the oxidant to form a layer of oxide film on the substrate. In examples that involve PEALD, a plasma may be used to react the film precursor with the oxidant. For example, the reaction can be performed using a radiofrequency power source to form a plasma comprising the oxidant. The radiofrequency power source may be operated at any suitable frequency (e.g., 400 kHz, 13.56 MHz) and power (e.g., between 0 and 7000 watts). The oxidant can be converted to oxygen-containing reactive species via the plasma. The oxygen-containing reactive species can then react with the adsorbed monolayer of film precursor to form a layer of oxide film on the substrate. Due to the inhibitor introduced at 906, the oxide film grows nonconformally. As such, a relatively thicker oxide film layer may be formed on a surface in the gap at the second depth corresponding to the lesser concentration of inhibitor. Likewise, a relatively thinner oxide film layer may be formed on a surface in the gap at the first depth corresponding to the greater concentration of inhibitor.

After reacting the film precursor with the oxidant, ALD cycle comprising an inhibitor 900 comprises purging the processing chamber at 912 to complete the ALD cycle comprising an inhibitor 900. In some examples, a purge may be omitted.

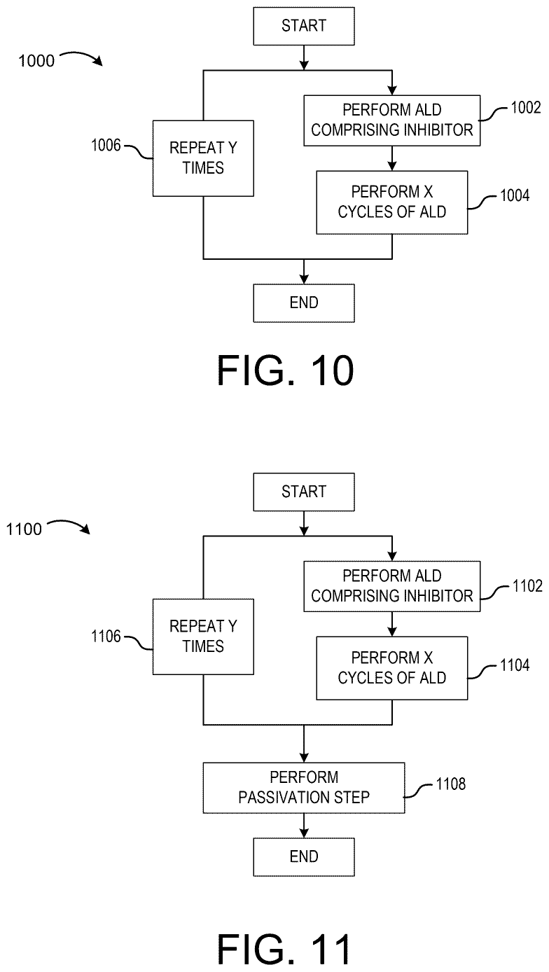

ALD processing may involve repeated ALD cycles. Such repeated ALD cycles may be performed in any suitable manner. FIG. 10 shows a flow diagram of an example method 1000 for performing ALD processing on a substrate comprising a gap between spacers. Method 1000 comprises one or more inhibited ALD cycles to help achieve nonconformal oxide film growth and fill the gap without forming a seam. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

As depicted in FIG. 10, method 1000 performs an inhibited ALD cycle at 1002. The inhibited ALD cycle may comprise introduction of any suitable inhibitor, such as a nitrogen-containing inhibitor, a fluorine-containing inhibitor, or a carbon-containing inhibitor. In some examples, the inhibitor may be deposited on the substrate by forming a plasma comprising the inhibitor. The inhibitor deposits into the gap such that a concentration of inhibitor deposited at a first depth within the gap is greater than a concentration of inhibitor deposited at a second depth within the gap, the second depth being deeper in the gap than the first depth. ALD cycle comprising an inhibitor 800 and ALD cycle comprising an inhibitor 900 are examples of ALD cycles that may be performed at 1002 to introduce an inhibitor.

At 1004, method 1000 performs a number “X” of ALD cycles omitting an inhibitor. At least some of the inhibitor deposited at 1002 may remain on the substrate through one or more of the ALD cycles performed at 1004. ALD cycle 700 is an example of an ALD cycle that may be performed at 1004. Any suitable number of ALD cycles may be performed with any suitable ratio 1:X of inhibited ALD cycles to ALD cycles omitting an inhibitor. For example, if a 1:1 ratio is desired, the ALD cycle may be performed once at 1004. As another example, two ALD cycles may be performed at 1004 resulting in a 1:2 ratio. In some examples, X=0 and no ALD cycles are performed omitting an inhibitor. A greater ratio of ALD cycles with inhibitor to ALD cycles that omit introducing inhibitor may result in a greater degree of oxide film nonconformality compared to a lower ratio.

The ALD cycles performed at 1002 and 1004 may be repeated any suitable number “Y” of times, as indicated at 1006. Once a sufficient oxide film thickness has been achieved, method 1000 may terminate. Due to inhibitor introduced at 1002, the oxide film grows nonconformally to fill the gap between spacers without forming a seam.

Various process variables may be adjusted to affect a degree of film conformality. As described above, a ratio of ALD cycles omitting an inhibitor to ALD cycles that include introducing an inhibitor can be adjusted to control the degree of nonconformal growth. As another example, varying a time of exposure to the inhibitor may vary a conformality of the oxide film. Additionally, one or more passivation steps may be performed during ALD processing to remove residual inhibitor from the substrate. In some examples, when performing ALD with a fluorine-containing inhibitor, the one or more passivation steps may help to avoid incorporation of fluorine into the oxide film. In some examples, a passivation step can be performed at the end of ALD processing. In some examples, passivation steps additionally or alternatively are performed between ALD cycles.

FIG. 11 shows a flow diagram of an example method 1100 for performing ALD processing with a passivation step. Method 1100 may be used to deposit an oxide film on a substrate comprising a gap between spacers. Method 1100 comprises one or more inhibited ALD cycles to grow the oxide film nonconformally and fill the gap without forming a seam. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

Method 1100 performs an ALD cycle comprising an inhibitor at 1102. ALD cycle comprising an inhibitor 800 and ALD cycle comprising an inhibitor 900 are examples of ALD cycles that may be performed at 1102. ALD cycle comprising an inhibitor 1102 may comprise introduction of any suitable inhibitor. Examples include a nitrogen-containing inhibitor, a fluorine-containing inhibitor, or a carbon-containing inhibitor. In some examples, the inhibitor may be deposited on the substrate by forming a plasma comprising the inhibitor.

At 1104, method 1100 performs a number “X” of ALD cycles omitting an inhibitor. ALD cycle 700 is an example of an ALD cycle that may be performed at 1104. In some examples, method 1100 may perform a number X between 1 and 20 ALD cycles at 1104. In other examples, any suitable number X of ALD cycles may be performed at 1104. The ALD cycles performed at 1102 and 1104 may be repeated any suitable number “Y” of times, as indicated at 1106. Due to inhibitor introduced at 1102, the oxide film grows nonconformally to fill the gap between spacers without forming a seam.

Once a sufficient oxide film thickness has been achieved, method 1100 may proceed to 1108 and perform a passivation step. Passivation helps remove residual inhibitor from the substrate. For example, an inhibitor that chemisorbs to the substrate at 1102 may at least partially remain on the substrate after performing the X ALD cycles at 1104. Inhibitor remaining on the substrate may affect subsequent processing. Thus, the passivation step may be performed at 1108 to remove the chemisorbed inhibitor. Where a fluorine-containing inhibitor or a nitrogen-containing inhibitor is used, a passivation step may comprise exposing the inhibitor adsorbed to the substrate surface to one or more of H₂ or O₂. Thermal and/or plasma energy may be used to facilitate the passivation. After performing the passivation step at 1108, method 1100 may terminate.

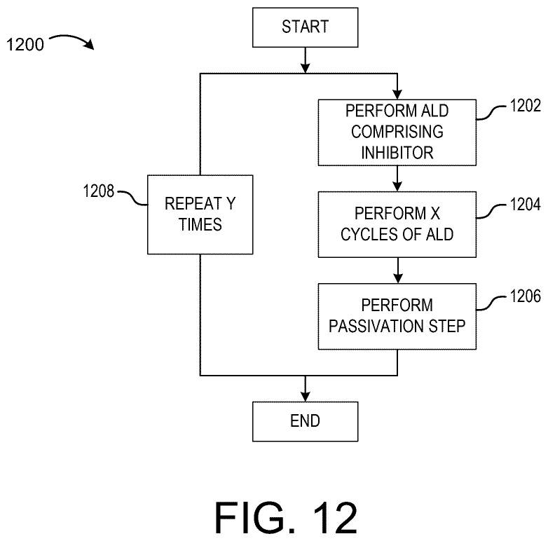

FIG. 12 shows a flow diagram of another example method 1200 for performing ALD processing with a passivation step. Method 1200 can be used to perform ALD processing on a substrate comprising a gap between spacers. Method 1200 comprises a plurality of ALD cycle comprising an inhibitor 1202 to help achieve nonconformal oxide film growth and fill the gap without forming a seam. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

Method 1200 comprises performing an ALD cycle comprising an inhibitor 1202. ALD cycle comprising an inhibitor 800 and ALD cycle comprising an inhibitor 900 are examples of inhibited ALD cycles that may be performed at 1202. ALD cycle comprising an inhibitor 1202 may comprise introduction of any suitable inhibitor. Examples include a nitrogen-containing inhibitor, a fluorine-containing inhibitor, or a carbon-containing inhibitor. The inhibitor deposits into the gap such that a concentration of inhibitor deposited at a first depth within the gap is greater than a concentration of inhibitor deposited at a second depth within the gap, the second depth being deeper in the gap than the first depth.

At 1204, method 1200 performs a number “X” of ALD cycles omitting an inhibitor. ALD cycle 700 is an example of an ALD cycle that may be performed at 1204. Any suitable number X of ALD cycles may be performed at 1204.

After performing an inhibited ALD cycle at 1202 and X ALD cycles at 1204, method 1200 comprises performing a passivation step at 1206. As described above, a passivation step can be performed to remove residual inhibitor from the substrate.

The ALD cycles performed at 1202 and 1204, and the passivation step performed at 1206 may be repeated any suitable number “Y” of times, as indicated at 1208. Thus, method 1200 includes one passivation step for every inhibited ALD cycle. Once a sufficient oxide film thickness has been achieved, method 1200 may terminate. Due to inhibitor introduced at 1202, the oxide film grows nonconformally to fill the gap between spacers without forming a seam. Further, a number Y of passivation steps are performed which may help avoid incorporation of inhibitor into the oxide film.

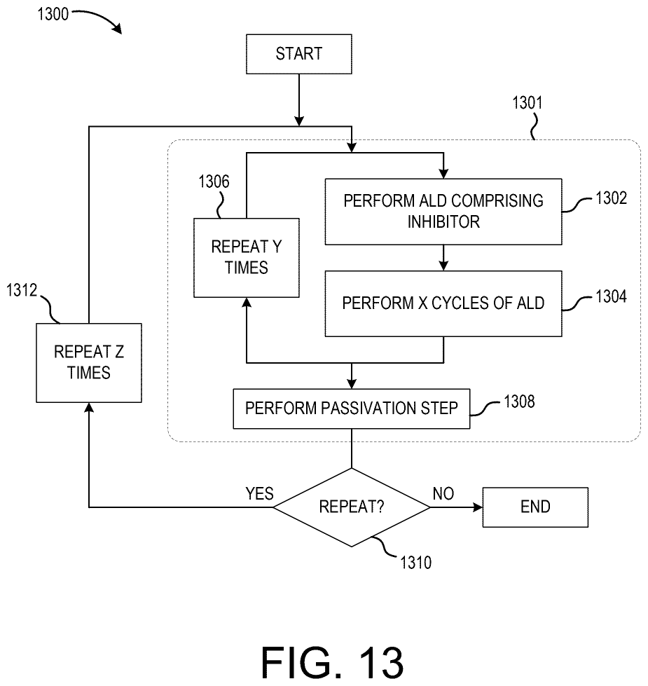

In some examples, passivation is performed at different intervals. FIG. 13 shows a flow diagram for an example method 1300 for performing one or more supercycles 1301. Each supercycle 1301 comprises at least one inhibited ALD cycle and at least one passivation step.

Method 1300 can be used to perform ALD processing on a substrate comprising a gap between spacers. Method 1300 comprises a plurality of ALD cycle comprising an inhibitor to help achieve nonconformal oxide film growth and fill the gap without forming a seam. Suitable oxide films include silicon dioxide, silicon oxynitride, silicon oxycarbide, aluminum oxide (Al₂O₃), hafnium oxide (HfOₓ), titanium oxide (TiOₓ), tungsten oxide (WOₓ), tin oxide (SnOₓ), and molybdenum oxide (MoOₓ) films.

As part of a supercycle 1301, method 1300 performs an ALD cycle comprising an inhibitor 1302. ALD cycle comprising an inhibitor 1302 may introduce any suitable inhibitor, such as a nitrogen-containing inhibitor, a fluorine-containing inhibitor, or a carbon-containing inhibitor. In some examples, the inhibitor may be deposited on the substrate using a plasma. The inhibitor deposits into the gap such that a concentration of inhibitor deposited at a first depth within the gap is greater than a concentration of inhibitor deposited at a second depth within the gap, the second depth being deeper in the gap than the first depth. ALD cycle comprising an inhibitor 800 and ALD cycle comprising an inhibitor 900 are examples of inhibited ALD cycles that may be performed at 1302.

At 1304, supercycle 1301 comprises performing a number “X” of ALD cycles omitting an inhibitor. ALD cycle 700 is an example of an ALD cycle that may be performed at 1204. Any suitable number X of ALD cycles may be performed at 1304. Further, the ALD cycles performed at 1302 and 1304 may be repeated any suitable number “Y” of times, as indicated at 1306. Due to inhibitor introduced at 1302, the oxide film grows nonconformally to fill the gap between spacers without forming a seam.

Continuing, at 1308, supercycle 1301 comprises performing a passivation step. Passivation helps remove residual inhibitor from the substrate.

After performing the passivation step at 1308, method 1300 may determine, at 1310, whether to perform additional supercycles 1301. If yes, method 1300 will repeat supercycle 1301. If no, method 1300 terminates. As indicated at 1312, method 1300 comprises repeating supercycle 1301 a number Z times. In contrast to method 1200 which comprises one passivation step, method 1300 comprises performing a plurality of passivation steps. Whereas method 1300 comprises one passivation step for every inhibited ALD cycle, method 1300 comprises performing a passivation step after every Y inhibited ALD cycles.

In other examples, ALD cycles, inhibited ALD cycles, and passivation steps may be performed any suitable number of times and in any suitable order.

Thus, oxide film growth on a substrate may be inhibited to different degrees on different substrate surfaces based upon a concentration of inhibitor deposited to the substrate surfaces. In patterning applications, the substrate can be exposed to the inhibitor under conditions that cause the inhibitor to deposit into a gap between spacers such that a concentration of inhibitor deposited at a first depth within the gap is greater than a concentration of inhibitor deposited at a second depth within the gap, the second depth being deeper in the gap than the first depth. As such, oxide film growth can be relatively faster on surfaces deeper in a gap compared to oxide film growth on surfaces near the opening of the gap. Use of an inhibitor may therefore help achieve a bottom-up gapfill to form an oxide film and avoid seam formation.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 14 schematically shows a non-limiting embodiment of a computing system 1400 that can enact one or more of the methods and processes described above. Computing system 1400 is shown in simplified form. Computing system 1400 may take the form of one or more personal computers, workstations, computers integrated with substrate processing tools, and/or network accessible server computers. Controller 230 is an example of computing system 1400.

Computing system 1400 includes a logic machine 1402 and a storage machine 1404. Computing system 1400 may optionally include a display subsystem 1406, input subsystem 1408, communication subsystem 1410, and/or other components not shown in FIG. 14.

Logic machine 1402 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 1404 includes one or more physical devices configured to hold instructions 1412 executable by the logic machine to implement the methods and processes described herein. When such methods and processes are implemented, the state of storage machine 1404 may be transformed—e.g., to hold different data.

Storage machine 1404 may include removable and/or built-in devices. Storage machine 1404 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 1404 may include volatile, nonvolatile, dynamic, static, read/write, read-only, random-access, sequential-access, location-addressable, file-addressable, and/or content-addressable devices.

It will be appreciated that storage machine 1404 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 1402 and storage machine 1404 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1406 may be used to present a visual representation of data held by storage machine 1404. This visual representation may take the form of a graphical user interface (GUI). As the herein described methods and processes change the data held by the storage machine, and thus transform the state of the storage machine, the state of display subsystem 1406 may likewise be transformed to visually represent changes in the underlying data. Display subsystem 1406 may include one or more display devices utilizing virtually any type of technology. Such display devices may be combined with logic machine 1402 and/or storage machine 1404 in a shared enclosure, or such display devices may be peripheral display devices.

When included, input subsystem 1408 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 1410 may be configured to communicatively couple computing system 1400 with one or more other computing devices. Communication subsystem 1410 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 1400 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of processing a substrate comprising a gap between spacers, the method comprising:
performing a plurality of atomic layer deposition (ALD) cycles to fill the gap between the spacers with an oxide film, an ALD cycle of the plurality of ALD cycles comprising exposing the substrate to an inhibitor under conditions configured to deposit inhibitor into the gap such that a concentration of the inhibitor deposited at a first depth within the gap is greater than a concentration of the inhibitor deposited at a second depth within the gap, the second depth being deeper in the gap than the first depth;
after filling the gap between the spacers, performing an etching cycle to expose the spacers; and
removing the spacers.

2. The method of claim 1, wherein the inhibitor comprises a carbon-containing inhibitor.

3. The method of claim 2, wherein the carbon-containing inhibitor comprises one or more of an alkane, an alkene, an alkyne, a cyclic hydrocarbon, an alcohol, a diol, an aldehyde, an ester, an ether, a ketone, an alkyl halide, an alkyl amine, or an alkyl diamine.

4. The method of claim 1, wherein the inhibitor comprises a nitrogen-containing inhibitor.

5. The method of claim 4, wherein the nitrogen-containing inhibitor comprises one or more of nitrogen, ammonia, an amine, a diamine, or an aminoalcohol.

6. The method of claim 1, wherein exposing the substrate to the inhibitor comprises forming a plasma comprising the inhibitor.

7. The method of claim 1, wherein the inhibitor comprises a fluorine-containing inhibitor.

8. The method of claim 7, wherein the fluorine-containing inhibitor comprises one or more of fluorine, nitrogen trifluoride, or a fluorocarbon.

9. The method of claim 1, further comprising performing an ALD cycle of the plurality of ALD cycles that omits exposing the substrate to the inhibitor.

10. The method of claim 1, wherein two or more ALD cycles of the plurality of ALD cycles comprise exposing the substrate to the inhibitor.

11. An atomic layer deposition (ALD) tool, comprising:
a processing chamber;
a substrate support disposed in the processing chamber;
a film precursor source comprising a film precursor;
an oxidant gas source comprising an oxidant;
an inhibitor source comprising an inhibitor;
flow control hardware configured to control flows of the film precursor, the oxidant, and the inhibitor into the processing chamber;
a radiofrequency power source configured to form a plasma in the processing chamber; and
a controller configured to control the ALD tool to:
operate the flow control hardware to introduce the inhibitor into the processing chamber under conditions configured to deposit inhibitor within a gap between spacers on a substrate such that a concentration of the inhibitor deposited at a first depth within the gap is greater than a concentration of the inhibitor deposited at a second depth within the gap, the second depth being deeper in the gap than the first depth,
operate the flow control hardware to introduce the film precursor to the processing chamber to adsorb the film precursor on the substrate, and
operate the flow control hardware and the radiofrequency power source to introduce the oxidant into the processing chamber and to form the plasma to oxidize the film precursor to form a layer of an oxide film.

12. The ALD tool of claim 11, wherein the film precursor comprises one or more of a silicon-containing precursor, an aluminum-containing precursor, a hafnium-containing precursor, a titanium-containing precursor, a tungsten-containing precursor, a tin-containing precursor, or a molybdenum-containing precursor.

13. The ALD tool of claim 11, wherein the inhibitor comprises a carbon-containing inhibitor.

14. The ALD tool of claim 13, wherein the carbon-containing inhibitor comprises one or more of an alkane, an alkene, an alkyne, a cyclic hydrocarbon, an aromatic, an alcohol, a diol, an aldehyde, an ester, an ether, a ketone, an alkyl halide, an alkyl amine, or an alkyl diamine.

15. The ALD tool of claim 11, wherein the inhibitor comprises a nitrogen-containing inhibitor.

16. The ALD tool of claim 11, wherein the inhibitor comprises fluorine-containing inhibitor.

17. The ALD tool of claim 11, wherein the controller is further configured to operate the ALD tool to perform a passivation step to remove at least some of the inhibitor from the substrate.

18. A structure formed on a substrate in an integrated circuit manufacturing process, the structure comprising:
a plurality of spacers located on a surface of the substrate, the plurality of spacers defining one or more gaps;
an oxide film at least partially filling the one or more gaps; and
an inhibitor deposited within the one or more gaps, a concentration of the inhibitor deposited at a first depth within the one or more gaps greater than a concentration of the inhibitor deposited at a second depth within the one or more gaps, the second depth being deeper in the one or more gaps than the first depth, the inhibitor configured to inhibit growth of the oxide film.

19. The structure of claim 18, wherein the substrate comprises a feature-dense region comprising the plurality of spacers, an expanse lacking features, and the inhibitor is further deposited on the expanse lacking features.

20. The structure of claim 18, wherein the oxide film comprises one of silicon oxide, tin oxide, titanium oxide, tungsten oxide, hafnium oxide, aluminum oxide, or molybdenum oxide.
